(19) United States
(12) Patent Application Publication
(10) Pub. No.: US 2014/0035165 A1
(43) Pub. Date: Feb. 6, 2014

(54) Pierced Substrate on Chip Module Structure

(71) Applicant: Shin-Dar Jan, Hsinchu City (TW)

(72) Inventor: Shin-Dar Jan, Hsinchu City (TW)

(73) Assignee: LARVIEW TECHNOLOGIES CORPORATION, Yangmei City (TW)

(21) Appl. No.: 13/565,600

(22) Filed: Aug. 2, 2012

(51) Int. Cl. H01L 23/48

(52) U.S. Cl. 257/777; 257/E23.01

(57) ABSTRACT

The present invention provides a pierced substrate on chip module structure comprising a first substrate. A chip is configured on the first substrate, with a first contact pad and a sensing area. A second substrate is disposed on the first substrate and the chip, with a concave structure, at least one through hole structure and a second contact pad, wherein the chip is disposed within the concave structure, and the first contact pad and the sensing area are exposed over the through hole structure. The first contact is coupled to the second contact pad via a wire. A transparent material is disposed on the second substrate, substantially aligning to the sensing area. A lens holder is disposed on the second substrate, and a lens is located on the top of the lens holder, substantially aligning to the transparent material and the sensing area.

### TECHNICAL FIELD

The present invention generally relates to semiconductor device structure, more particularly, to a pierced substrate on chip module structure by integrating a lens holder and an image sensor to reduce the device size.

### BACKGROUND

In the field of semiconductor devices, the device density is increased and the device dimension is reduced, continuously. Conventionally, in the flip-chip attachment method, an array of solder bumps is formed on the surface of the die. The formation of the solder bumps may be carried out by using a solder composite material through a solder mask for producing a desired pattern of solder bumps. The function of chip package includes power distribution, signal distribution, heat dissipation, protection and support . . . and so on. As a semiconductor chip become more complicated, the traditional package technique, for example lead frame package, flex package, rigid package technique, can't meet the demand of producing smaller chip with high density elements on the chip. Wafer level package (WLP) technique is an advanced packaging technology, by which the dice are manufactured and tested on the wafer, and then the wafer is singulated by dicing for assembly in a surface-mount line. Because the wafer level package technique utilizes the whole wafer as one object, not utilizing a single chip or die, and therefore, before performing a scribing process, packaging and testing has been accomplished. Furthermore, WLP is such an advanced technique so that the process of wire bonding, die mount and under-fill can be omitted. By utilizing WLP technique, the cost and manufacturing time can be reduced, and the resulting structure of WLP can be equal to the die; therefore, this technique can meet the demands of miniaturization of electronic devices.

Currently, the flip chip technology used for the camera module is performed as a stud bump process on the entire wafer by a wire bonding equipment, whereby solder balls to being replaced by the stud bumps.

A CMOS image sensor is manufactured into a CMOS image sensor module from a CMOS image sensor chip by an electronic package technology. And it is applied into various goods and a package specification required by the CMOS image sensor module depends on characteristics of the finished goods. Especially, the recent tendencies of a CMOS image sensor module, namely, high electricity capabilities, miniaturization/high density, a low power consumption, multifunction, a high speed signal processing, a reliability are the representative characteristics of a miniaturization of the electronic goods.

Contrary to general CMOS chips, the CMOS image sensor in the past is feasible to a physical environment and can be polluted by the impurities, and a leadless chip carrier LCC type package is used when its size is not considered to be important. However, in a recent tendency of a market requiring for thin and simplified characteristics such as in a camera phone, smart phone, chip-on-board (COB), chip-on-film (COF), chip size package (CSP), etc. are generally used.

Current flip chip structure can reduce module height but flip chip machine is very expensive and low UPH (Unit Per Hour). So, the investment is very huge. And, yield is lower and not easy to be controlled.

Therefore, based-on the shortcomings of prior arts, the present invention provide a newly pierced substrate on chip module structure, which has no need for new investment and the process yield will be better.

### SUMMARY OF THE INVENTION

Based-on the shortcomings of the above-mentioned, an objective of the present invention is to provide a pierced substrate on chip module structure with a smaller height of the module structure.

Another objective of the present invention is to provide a pierced substrate on chip module structure by integrating a lens holder and an image sensor to reduce the device size, and enhancing yield and reliability.

Yet another objective of the present invention is to provide a pierced substrate on chip module structure with good thermal performance, lower cost and easy to manufacture.

According to an aspect of the present invention, the present invention provides a pierced substrate on chip module structure. The module structure comprises a first substrate. A chip is configured on the first substrate, with a first contact pad and a sensing area. A second substrate is disposed on the first substrate and the chip, with a concave structure, at least one through hole structure and a second contact pad, wherein the chip is disposed within the concave structure, and the first contact pad exposing for the first through hole structure and the sensing area exposing for the second through hole structure. The first contact is coupled to the second contact pad via a wire. A transparent material is disposed on the second substrate, substantially aligning to the sensing area. A lens holder is disposed on the second substrate, and a lens is located on the top of the lens holder, substantially aligning to the transparent material and the sensing area.

The module structure further comprises at least one passive component or active component configured on the first substrate and/or the second substrate. The first substrate is adhered to the second substrate via a conductive layer for electrically connecting with each other. Material of the second substrate comprises epoxy type FR5 or FR4, BT(Bismaleimide Triazine), glass, silicon or ceramic, wherein the printed circuit board and the flexible printed circuit board has its trace formed thereon, respectively. The chip is adhered to the first substrate via a conductive layer or a non-conductive adhesion layer. The lens holder is adhered to the second substrate via an adhesion layer.

### BRIEF DESCRIPTION OF THE DRAWINGS

The components, characteristics and advantages of the present invention may be understood by the detailed descriptions of the preferred embodiments outlined in the specification and the drawings attached:

FIG. 1 illustrates a sectional view of a flip chip package structure;

FIG. 2 illustrates a sectional view of another example of a flip chip package structure;

FIG. 3 illustrates a sectional view of a pierced substrate on chip module structure by integrating a lens holder and an image sensor chip according to the present invention;

FIG. 4 illustrates a sectional view of a pierced substrate on chip module structure according to another embodiment of the present invention;

FIG. 5 illustrates a top view of the substrate of the present invention.

### DETAILED DESCRIPTION

Some preferred embodiments of the present invention will now be described in greater detail. However, it should be recognized that the preferred embodiments of the present invention are provided for illustration rather than limiting the present invention. In addition, the present invention can be practiced in a wide range of other embodiments besides those explicitly described, and the scope of the present invention is not expressly limited except as specified in the accompanying claims.

The present invention provides a pierced substrate on chip module structure which can be manufactured by employing a chip-on-board (COB) packaging technique. The chip-on-board (COB) packaging technique is used for the integrated circuit packaging, which the chip is adhered on the circuit board or substrate, and thereby effectively performing chip packaging and testing based-on the circuit board assembly.

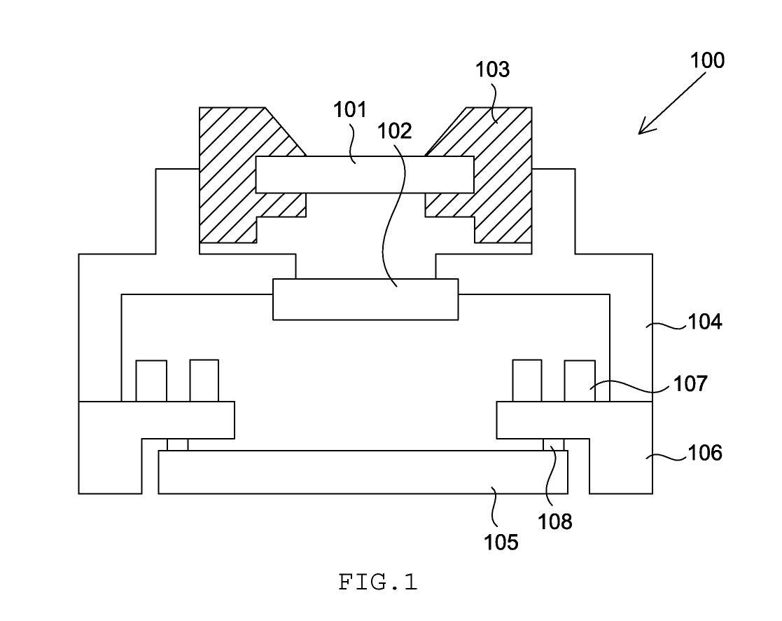

FIG. 1 shows a sectional view of a flip chip package structure. As shown in FIG. 1, the flip chip package structure 100 comprises a substrate 106, a chip 105, a passive component 107, a lens holder 104, a lens 101 and a transparent plate (material) 102. The substrate 106 has a concave structure formed therein for receiving the chip 105 and a conductive layer 108. The chip 105 and the conductive layer 108 are formed under the substrate 106, wherein the conductive layer 108 is electrically connected to the substrate 106 and a contact pad of the chip 105. The lens holder 104 includes a jig 103 for fixing the lens 101. At least one passive component 107 is formed (adhered) on the substrate 106 within the lens holder 104. The lens 101 is disposed on the upper portion of the lens holder 104. Moreover, the transparent plate 102 is optionally disposed within the lens holder 104, between the lens 101 and the chip 105. The lens holder 104 is adhered to the substrate 106 via an adhesion layer.

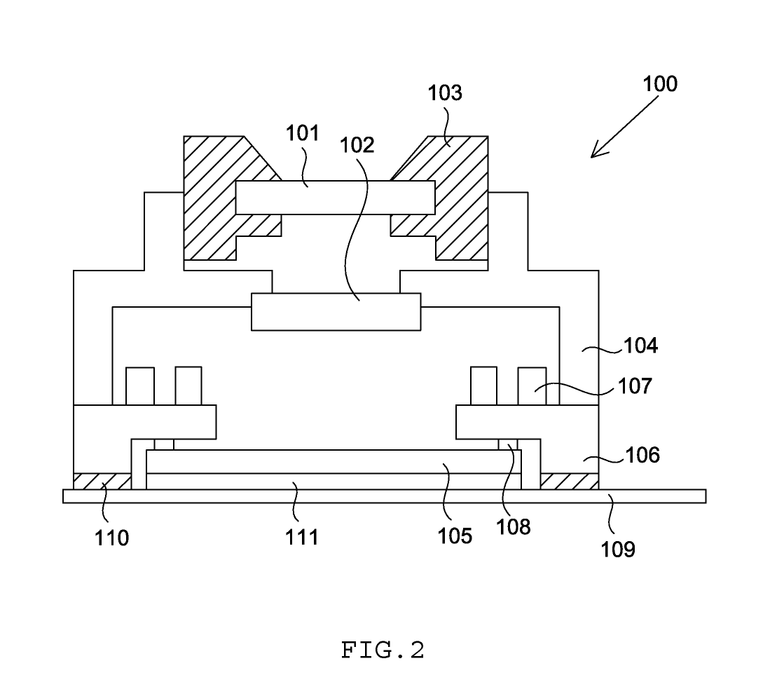

FIG. 2 shows a sectional view of another example of a flip chip package structure. As shown in FIG. 2, the flip chip package structure 100 further comprises a printed circuit board 109 with a conductive wire for electrically connecting to other device, a conductive layer 110 and a heat dissipation layer 111. The heat dissipation layer 111 is formed between the chip 105 and the printed circuit board 109 for facilitating heat dissipation. The substrate 106 is adhered to the printed circuit board 109 via the conductive layer 110 for electrically connecting to each other.

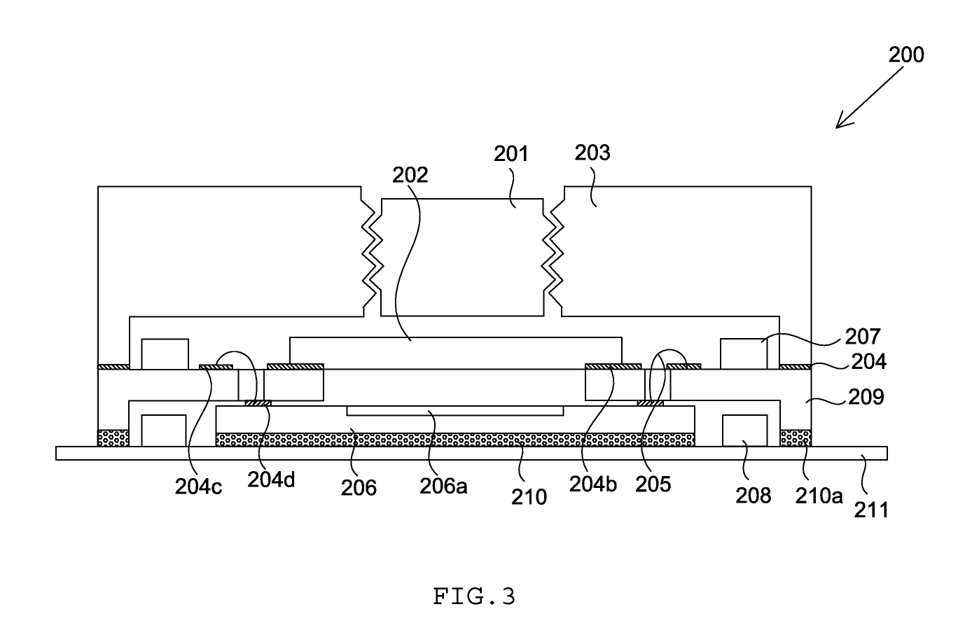

FIG. 3 shows a sectional view of a pierced substrate on chip module structure by integrating a lens holder and an image sensor chip according to the present invention. As shown in FIG. 3, the pierced substrate on chip module structure 200 integrates the lens holder and the image sensor chip to be as a module structure with sensing function, which can be applied to a camera module of a mobile phone. The pierced substrate on chip module structure 200 comprises a pierced substrate 209 and a substrate 211, a chip 206, active or passive components 207 and 208, a lens holder 203, a lens 201 and a transparent plate (material) 202.

The chip 206 may be adhered on (to) the substrate 211 via a conductive layer or a non-conductive adhesion layer. In one embodiment, the active or passive components 208 are electrically connected to conductive wire of the substrate 211. For example, the chip 206 is an image sensor chip which has a sensing area 206a on its surface and a contact pad 204d formed thereon. The active component 208 is a semiconductor integrated circuit (IC), and the passive component 208 includes a capacitor or an inductor. The substrate 211 is a printed circuit board or a flexible printed circuit board.

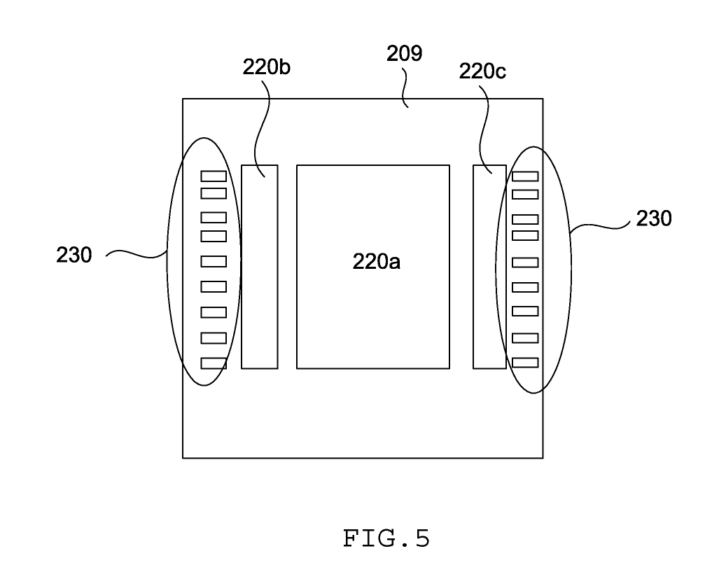

In one embodiment, the substrate 209 has a concave structure formed therein for receiving the chip 206 and for the active component or passive component 208 located within the concave structure, and a through hole structure with opening area 220a, 220b and 220c for facilitating exposing the sensing area 206a and the contact pad 204d of the chip 206, shown as FIG. 5. Configuration and number of the opening is illustrated only, but not limited to the present invention. Size of the substrate 209 is larger than that of the chip 206. For example, the through hole structure (opening area 220a, 220b, 220c) is formed within the substrate 209 by employing a punching or drilling process. The opening area 220a, 220b, 220c is substantially aligning to the sensing area 206a and the contact pad (I/O pad) 204d. Moreover, a contact pad 204c is formed on the substrate 209. Based-on the concave structure of the substrate 209, the module structure has more space for component placement.

A wire 205 is electrically connected to the contact pad 204c of the substrate 209 and the contact pad 204d of the chip 206. The contact pad 204c is formed on the wire bonding area 230 of the substrate 209. The transparent plate 202 is configured on the substrate 209. An adhesion layer 204b is formed on the substrate 209, and the transparent plate 202 is adhered to the substrate 209 via the adhesion layer 204b. The transparent plate 202 is, for example a glass substrate or the substrate made of a transparent material. The transparent plate 202 is located above the substrate 209 for covering the sensing area 206a, and thereby creating a gap between the transparent plate 202 and the sensing area 206a. The transparent plate 202 covers the sensing area 206a of the image sensor chip 206 to reduce particles contamination for enhancing yield of the module structure. Size of the transparent plate 202 may be the same or larger than area of the sensing area 206a. Besides, at least one passive component 207 is adhered on (to) the substrate 209 within the lens holder.

The transparent plate (glass substrate) 202 may be round or square type. The transparent plate (glass substrate) 202 may be optionally coated infrared coating for filtering, such as infrared filter for filtering to a certain band of frequency by passing through the lens 201.

The lens holder 203, which may be a plastic piece or an actuator, is adhered on the substrate to complete the module structure 200 of the present invention. An adhesion layer 204 is formed on the substrate 209, and the bottom of the lens holder 203 is adhered on the substrate 209 via the adhesion layer 204. The lens 201 is fixed to the lens holder 203 for supporting the lens 201. Moreover, the lens holder may be fixed to the substrate 209 for supporting the lens 201. The lens 201 may be optionally disposed above the lens holder 203. The module structure 200 of this embodiment, the transparent plate 202 may be optionally disposed within the lens holder 203, and between the lens 201 and the chip 206. In other words, the lens 201 is substantially aligning to the transparent plate 202 and the chip 206. Trace of the substrate 209 may be electrically connected to trace of the substrate 211 via the conductive layer 210a. The conductive layer 210a may be an adhesion layer formed on two-side of the substrate 209. In one embodiment, material of the conductive layer 210a includes a conductive paste or a conductive film, which may be formed as a pattern paste on the substrate by employing a printing or coating process. The conductive layer 210a may be optically coated on the substrate 211. Size of the substrate 211 is larger than that of the substrate 209 such that the substrate 211 can extend to outside of the substrate 209 when the two substrates are combined by adhering. It should be noted that the lens holder 203, the transparent plate 202, the substrate 209, a portion of the substrate 211 and the image sensor chip 206 may be integrated into a cubic module structure. Based-on the substrate 211 extending to outside of the cubic module structure, electrical signals of the module structure 200 can be transmitted to other elements outside of the cubic module structure via the trace of the substrate 211.

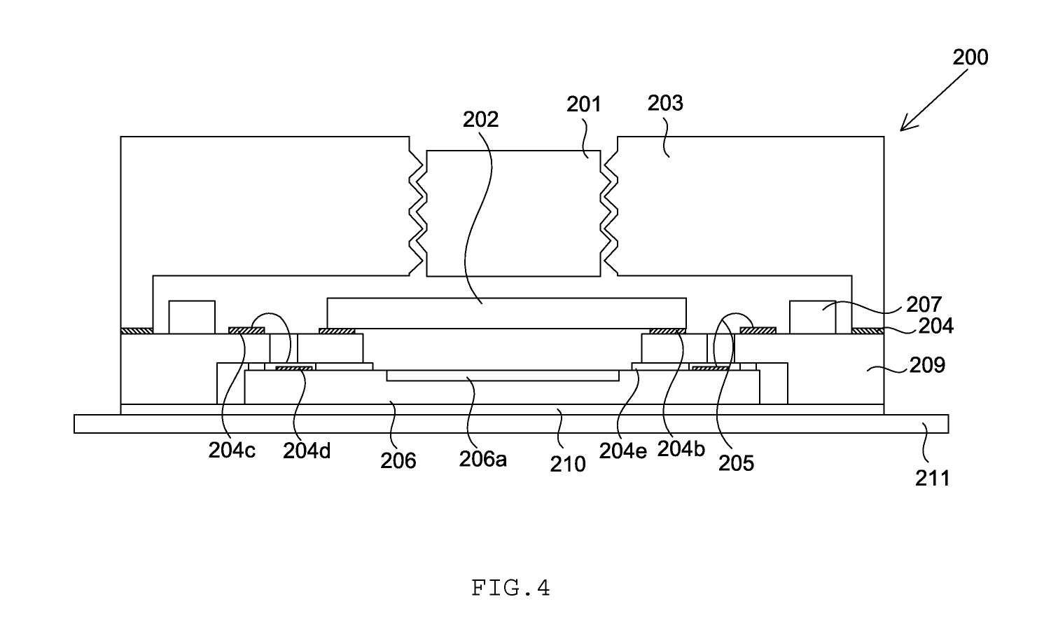

As shown in FIG. 4, it shows a sectional view of a pierced substrate on chip module structure according to another embodiment of the present invention. In this embodiment, the substrate 209 is adhered to the surface of the chip 206. In this embodiment, between the substrate 209 and the surface of the chip 206 is adhered from each other via an adhesion layer pattern 204e. The chip 206 is formed (adhered) on the substrate 211. In other words, the substrate 209 and the chip 206 are together adhered to the substrate 211 via the conductive layer 210. Other configuration of the module structure of this embodiment is similar with that of the FIG. 3, and therefore the detailed description is omitted.

In one embodiment of the present invention, the substrate 209 is a printed circuit board. Besides, the substrate 209 may be an organic substrate with a pre-determined through hole, and which material includes, for example epoxy type FR5 or FR4, or BT (Bismaleimide Triazine). Moreover, glass, ceramic and silicon may be as material of the substrate 209.

The advantages of the present invention comprises smaller height of the module structure, more space for component placement, using current wire bonding process (electrical connect method) which is easy and cheap, good thermal performance and easy to manufacture multiple chip packaging.

The foregoing descriptions are preferred embodiments of the present invention. As is understood by a person skilled in the art, the aforementioned preferred embodiments of the present invention are illustrative of the present invention rather than limiting the present invention. The present invention is intended to cover various modifications and similar arrangements included within the spirit and scope of the appended claims, the scope of which should be accorded the broadest interpretation so as to encompass all such modifications and similar structures.

What is claimed is:

1. A pierced substrate on chip module structure, comprising:
a first substrate;
a chip configured on said first substrate, with a first contact pad and a sensing area;
a second substrate disposed on said first substrate and said chip, with a concave structure,
a first through hole structure, a second through hole structure and a second contact pad,
wherein said chip is disposed within said concave structure, and wherein said first contact pad is electrically connected to said second contact pad via a wire, and said first contact pad exposing for said first through hole structure and said sensing area exposing for said second through hole structure; and
a lens holder disposed on said second substrate, and a lens located on said lens holder, substantially aligning to said sensing area.

2. The module structure of claim 1, further comprising at least one passive component or active component configured on said first substrate and/or said second substrate.

3. The module structure of claim 1, wherein said first substrate is adhered to said second substrate via a conductive layer.

4. The module structure of claim 1, wherein said first substrate is a printed circuit board or a flexible printed circuit board, and said second substrate is a printed circuit board, and material of said second substrate comprises epoxy type FR5 or FR4, BT(Bismaleimide Triazine), glass, silicon or ceramic, wherein said printed circuit board and said flexible printed circuit board has its trace formed thereon, respectively.

5. The module structure of claim 1, wherein said chip is adhered to said first substrate via a conductive layer or a non-conductive adhesion layer.

6. The module structure of claim 1, wherein said second substrate is adhered to said chip via an adhesion layer.

7. The module structure of claim 1, wherein said lens holder is adhered to said second substrate via an adhesion layer.

8. The module structure of claim 1, further comprising a transparent material disposed on said second substrate and said chip, substantially aligning to said sensing area.

9. The module structure of claim 8, further comprising at least one passive component or active component configured on said first substrate and/or said second substrate.

10. The module structure of claim 8, wherein said first substrate is adhered to said second substrate via a conductive layer.

11. The module structure of claim 8, wherein said first substrate is a printed circuit board or a flexible printed circuit board, and said second substrate is a printed circuit board, and material of said second substrate comprises epoxy type FR5 or FR4, BT(Bismaleimide Triazine), glass, silicon or ceramic, wherein said printed circuit board and said flexible printed circuit board has its trace formed thereon, respectively.

12. The module structure of claim 8, wherein said chip is adhered to said first substrate via a conductive layer or a non-conductive adhesion layer.

13. The module structure of claim 8, wherein said second substrate is adhered to said chip via an adhesion layer.

14. The module structure of claim 8, wherein said lens holder is adhered to said second substrate via an adhesion layer.
